(19) United States
(12) Patent Application Publication
(10) Pub. No.: US 2017/0133217 A1
(43) Pub. Date: May 11, 2017

(54) SEMICONDUCTOR SUBSTRATE AND SEMICONDUCTOR DEVICE

(71) Applicants: SANKEN ELECTRIC CO., LTD., Niiza-shi, Saitama (JP); SHIN-ETSU HANDOTAI CO., LTD., Tokyo (JP)

(72) Inventors: Ken SATO, Miyoshi-machi (JP); Hiroshi SHIKAUCHI, Niiza-shi (JP); Hirokazu GOTO, Minato-ku (JP); Masaru SHINOMIYA, Annaka (JP); Keitaro TSUCHIYA, Takasaki (JP); Kazunori HAGIMOTO, Takasaki (JP)

(73) Assignees: SANKEN ELECTRIC CO., LTD., Niiza-shi, Saitama (JP); SHIN-ETSU HANDOTAI CO., LTD., Tokyo (JP)

(21) Appl. No.: 15/300,472

(22) PCT Filed: Mar. 5, 2015
(86) PCT No.: PCT/JP2015/001196

§ 371 Date: Sep. 29, 2016

(30) Foreign Application Priority Data
Apr. 9, 2014 (JP) 2014-080323

(51) Int. Cl. H01L 21/02; H01L 29/66; H01L 29/207; H01L 29/778; H01L 29/20; H01L 29/205

(52) U.S. Cl. CPC H01L 21/0251; H01L 29/2003; H01L 29/205; H01L 29/207; H01L 29/7787; H01L 29/66462; H01L 21/02458; H01L 21/0254

(57) ABSTRACT

A semiconductor substrate including: substrate; buffer layer provided on substrate; high-resistance layer provided on buffer layer, high-resistance layer being composed of nitride-based semiconductor and containing transition metal and carbon; and channel layer provided on high-resistance layer, channel layer being composed of nitride-based semiconductor, wherein high-resistance layer includes reduction layer in contact with channel layer, reduction layer being layer in which concentration of transition metal is reduced from side where buffer layer is located toward side where channel layer is located, and reduction rate at which carbon concentration is reduced toward channel layer is higher than reduction rate at which concentration of transition metal is reduced toward channel layer. As a result, it is possible to provide a semiconductor substrate that can make higher resistance of region of high-resistance layer on side where channel layer is located while reducing carbon concentration and transition metal concentration in channel layer.

### BACKGROUND OF THE INVENTION

1. Field of the Invention

The present invention relates to a semiconductor substrate and a semiconductor device fabricated by using this semiconductor substrate.

2. Description of the Related Art

A semiconductor substrate using a nitride semiconductor is used in power devices and so forth which operate at high frequencies and high output power. In particular, as the power device suitable for performing amplification in high-frequency bands such as microwaves, submillimeter waves, and millimeter waves, a high electron mobility transistor (High Electron Mobility Transistor: HEMT) or the like is known.

As the semiconductor substrate using a nitride semiconductor, a semiconductor substrate having a Si substrate on which a buffer layer, a GaN layer, and a barrier layer composed of AlGaN are sequentially stacked is known.

By increasing the vertical and transverse electrical resistance of a lower layer (a high-resistance layer) of the GaN layer, it is possible to improve the OFF characteristics of a transistor and make the transistor withstand a higher voltage by the suppression of vertical leakage. For this reason, the GaN layer is doped with carbon to form a deep level in a GaN crystal and thereby suppress n-type conduction.

On the other hand, since an upper layer of the GaN layer functions as a channel layer and, if a level that traps carriers is formed therein, this may become a factor responsible for a reduction in mobility due to impurity scattering or current collapse (a phenomenon in which the reproducibility of output current characteristics is reduced), it is necessary to reduce the concentrations of carbon and the like to sufficiently low levels (refer to Patent Literatures 1 to 3).

Moreover, in Patent Literature 4, achieving an increase in resistance by adding Fe to a GaN layer is disclosed (refer to FIG. 6) and further adding carbon in order to stabilize the energy level of Fe is also disclosed (refer to FIG. 7).

### CITATION LIST

### Patent Literatures

Patent Literature 1: Japanese Patent No. 5064824

Patent Literature 2: Japanese Unexamined Patent Application Publication (Kokai) No. 2006-332367

Patent Literature 3: Japanese Unexamined Patent Application Publication (Kokai) No. 2013-070053

Patent Literature 4: Japanese Unexamined Patent Application Publication (Kokai) No. 2012-033646

Patent Literature 5: Japanese Patent No. 5013218

### SUMMARY OF THE INVENTION

However, if Fe is added to the GaN layer as disclosed in Patent Literature 5, since Fe is contained also in an upper GaN layer thereof like a skirt trailed, it is necessary to add carbon also to the upper GaN layer in order to stabilize the energy level of Fe.

However, since a region 119 of a GaN layer 116 shown in FIG. 6 on the side where an electron supply layer 118 is located functions as a channel layer, it is not desirable to add carbon to the GaN layer which becomes an active layer for the reason described above.

Thus, as shown in FIG. 8, the carbon concentration may be gradually reduced in a second GaN layer 122 toward the side where a third GaN layer 124 functioning as a channel layer is located with the same timing as Fe, but, in that case, a region of the second GaN layer 122 on the side where the third GaN layer 124 is located does not contain much Fe nor carbon, and resistance in thickness and transverse directions is reduced, which causes this layer to stop functioning as a high-resistance layer sufficiently.

The present invention has been made in view of the above-described problem, and an object thereof is to provide a semiconductor substrate that can implement a high-resistance layer of higher resistance while reducing the carbon concentration and a transition metal concentration in a channel layer and to provide a semiconductor device fabricated by using this semiconductor substrate.

To attain the above-described object, the present invention provides a semiconductor substrate including: a substrate; a buffer layer provided on the substrate; a high-resistance layer provided on the buffer layer, the high-resistance layer being composed of a nitride-based semiconductor and containing a transition metal and carbon; and a channel layer provided on the high-resistance layer, the channel layer being composed of a nitride-based semiconductor, wherein the high-resistance layer includes a reduction layer in contact with the channel layer, the reduction layer being the layer in which the concentration of the transition metal is reduced from the side where the buffer layer is located toward the side where the channel layer is located, and the reduction rate at which the carbon concentration is reduced toward the channel layer is higher than the reduction rate at which the concentration of the transition metal is reduced toward the channel layer.

As described above, by providing, in the high-resistance layer, the reduction layer in contact with the channel layer, the reduction layer being the layer in which the concentration of the transition metal is reduced from the side where the buffer layer is located toward the side where the channel layer is located and making the reduction rate at which the carbon concentration is reduced toward the channel layer higher than the reduction rate at which the concentration of the transition metal is reduced toward the channel layer, it is possible to increase the carbon concentration to a region of the reduction layer which is closer to the side where the channel layer is located and, at the same time, reduce the carbon concentration in the channel layer, whereby it is possible to reduce the carbon concentration and the transition metal concentration in the channel layer while maintaining the high resistance of the high-resistance layer on the side where the channel layer is located.

At this time, it is preferable that the average carbon concentration of the channel layer is lower than the average carbon concentration of the reduction layer.

With such a configuration, it is possible to make higher the resistance of the high-resistance layer in a thickness direction while suppressing the occurrence of current collapse and a reduction in the mobility of carriers in the channel layer.

At this time, it is preferable that the carbon concentration of the reduction layer on the side where the buffer layer is located to a portion in which the carbon concentration is reduced is increased from the side where the buffer layer is located toward the side where the channel layer is located or is constant.

With such a configuration, since it is possible to make up for a reduction in the concentration of the transition metal with carbon, it is possible to suppress more reliably a reduction in resistance caused by a reduction in the concentration of the transition metal in the reduction layer.

At this time, it is preferable that, in the reduction layer, the sum of the carbon concentration and the transition metal concentration is 1×10¹⁸ atoms/cm³ or more but 1×10²⁰ atoms/cm³ or less.

If the sum of the carbon concentration and the transition metal concentration is within the above-described range, it is possible to maintain the high resistance of the reduction layer suitably.

At this time, it is preferable that the thickness of the reduction layer is 500 nm or more but 3 μm or less and, in the reduction layer, the transition metal is reduced from a concentration of 1×10¹⁹ atoms/cm³ or more but 1×10²⁰ atoms/cm³ or less to a concentration of 1×10¹⁶ atoms/cm³ or less.

If the thickness of the reduction layer is 500 nm or more, it is possible to reduce the concentration of the transition metal to a sufficiently low concentration, and, if the thickness of the reduction layer is 3 μm or less, it is possible to prevent a crack from being easily produced on the periphery of the substrate.

Moreover, as the concentration gradient of the transition metal in the reduction layer, the above-described concentration gradient can be suitably used.

At this time, it is preferable that the high-resistance layer further includes a layer in which the concentration of the transition metal is constant.

With such a configuration, since it is possible to make the high-resistance layer thicker, it is possible to make a vertical (thickness-direction) leakage current smaller.

At this time, the transition metal may be Fe.

As described above, Fe can be suitably used as the transition metal.

Moreover, the present invention provides a semiconductor device that is a semiconductor device fabricated by using the above-described semiconductor substrate, wherein an electrode is provided on the channel layer.

As described above, according to the semiconductor device fabricated by using the semiconductor substrate of the present invention, since it is possible to increase the carbon concentration to a region of the reduction layer which is closer to the side where the channel layer is located and, at the same time, reduce the carbon concentration in the channel layer, it is possible to reduce the carbon concentration and the transition metal concentration in the channel layer while maintaining the high resistance of the high-resistance layer on the side where the channel layer is located, whereby it is possible to make a transistor withstand a higher voltage by the suppression of vertical leakage by increasing vertical electrical resistance while suppressing a reduction in the mobility of carriers in the channel layer.

As described above, according to the present invention, since it is possible to increase the carbon concentration to a region of the reduction layer which is closer to the side where the channel layer is located and, at the same time, reduce the carbon concentration in the channel layer, it is possible to make higher the resistance of the high-resistance layer on the side where the channel layer is located while reducing the carbon concentration and the transition metal concentration in the channel layer, whereby, by increasing vertical electrical resistance while suppressing a reduction in the mobility of carriers in the channel layer, it is possible to improve the OFF characteristics of a transistor and make the transistor withstand a higher voltage by the suppression of vertical leakage. As a result, with the semiconductor substrate of the present invention, it is possible to fabricate a high-quality power device such as an HEMT.

### BRIEF DESCRIPTION OF DRAWINGS

FIG. 1 is a diagram showing the depth-direction concentration distribution of a semiconductor substrate which is an example of an embodiment of the present invention;

FIG. 2 is a sectional view of the semiconductor substrate which is an example of the embodiment of the present invention;

FIG. 3 is a sectional view of a semiconductor device which is an example of the embodiment of the present invention;

FIG. 4 is a diagram showing the Vds dependence of current collapse in Example and Comparative Example 1;

FIG. 5 is a diagram showing the relationship between a vertical leakage current and a vertical voltage in Example and Comparative Example 2;

FIG. 6 is a diagram showing the depth-direction concentration distribution of a conventional semiconductor substrate in which Fe is doped to a GaN layer;

FIG. 7 is a diagram showing the depth-direction concentration distribution of a conventional semiconductor substrate in which Fe and carbon is doped to a GaN layer;

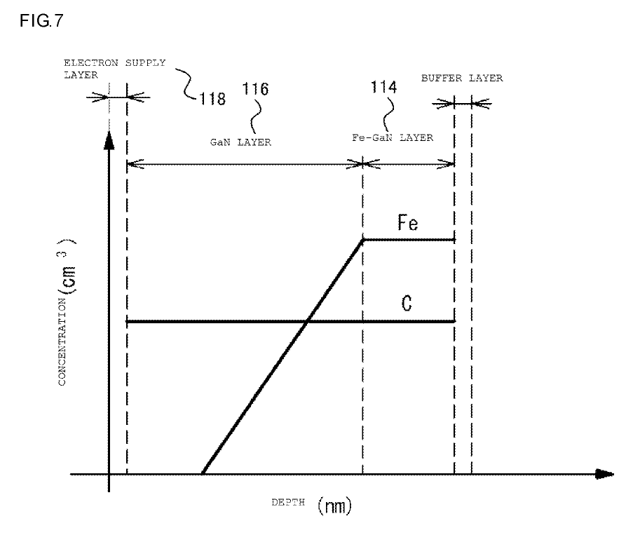

FIG. 8 is a diagram showing the depth-direction concentration distribution of a conventional semiconductor substrate in which Fe and carbon is doped to a GaN layer and concentration of the carbon is sloped;

FIG. 9 is a diagram showing the depth-direction concentration distribution of a semiconductor substrate of Comparative Example 1; and

FIG. 10 is a diagram showing the depth-direction concentration distribution of a semiconductor substrate of Comparative Example 2.

### DETAILED DESCRIPTION OF THE PREFERRED EMBODIMENTS

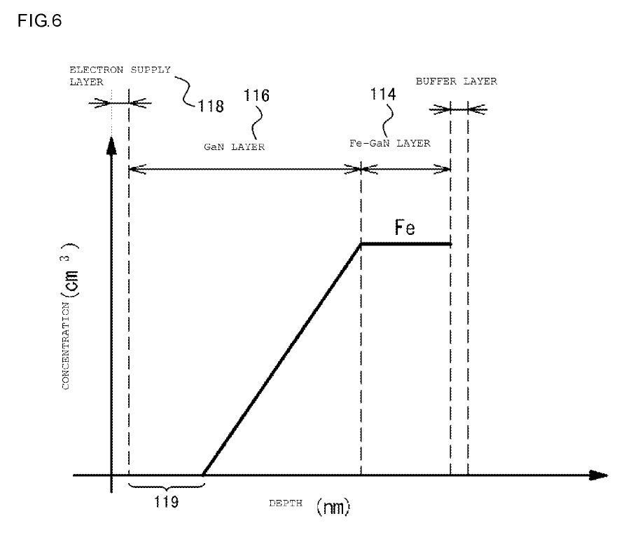

As described above, if Fe is added to a GaN layer, since Fe is contained also in an upper GaN layer thereof like a skirt trailed, it is necessary to add carbon also to the upper GaN layer in order to stabilize the energy level of Fe, but, since a region 119 of a GaN layer 116 shown in FIG. 6 on the side where an electron supply layer 118 is located functions as a channel layer, it is not desirable to add carbon to the GaN layer which becomes an active layer for the reason described above.

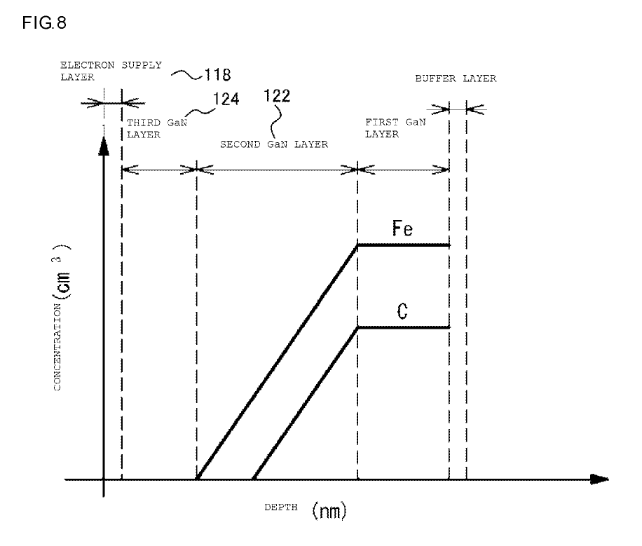

Thus, as shown in FIG. 8, the carbon concentration may be gradually reduced in a second GaN layer 122 toward the side where a third GaN layer 124 functioning as a channel layer is located with the same timing as Fe, but, in that case, a region of the second GaN layer 122 on the side where the third GaN layer 124 is located does not contain much Fe nor carbon, and resistance in thickness and transverse directions is reduced, which causes this layer to stop functioning as a high-resistance layer sufficiently.

The present inventors keenly studied a semiconductor substrate that can implement a high-resistance layer of higher resistance while reducing a carbon concentration and a transition metal concentration in a channel layer. As a result, the present inventors have found out that, by providing, in a high-resistance layer, a reduction layer in contact with a channel layer, the reduction layer being the layer in which the concentration of a transition metal is reduced from the side where a buffer layer is located toward the side where the channel layer is located, and making the reduction rate at which the carbon concentration is reduced toward the channel layer higher than the reduction rate at which the concentration of the transition metal is reduced toward the channel layer, it is possible to increase the carbon concentration to a region of the reduction layer which is closer to the channel layer and, at the same time, reduce the carbon concentration in the channel layer, whereby it is possible to implement a high-resistance layer of higher resistance while reducing the carbon concentration and the transition metal concentration in the channel layer, thereby bringing the present invention to completion.

Hereinafter, the present invention will be described in detail as an example of an embodiment with reference to the drawings, but the present invention is not restricted thereto.

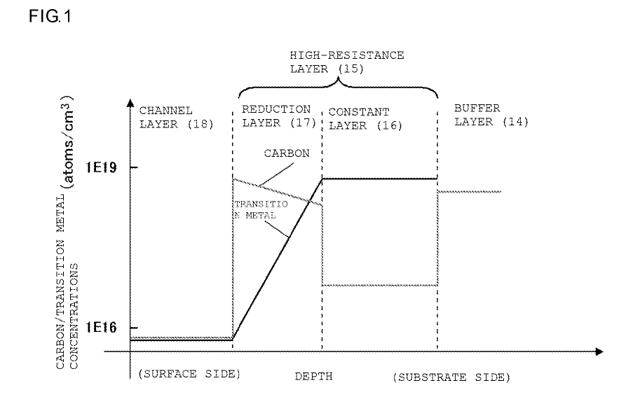

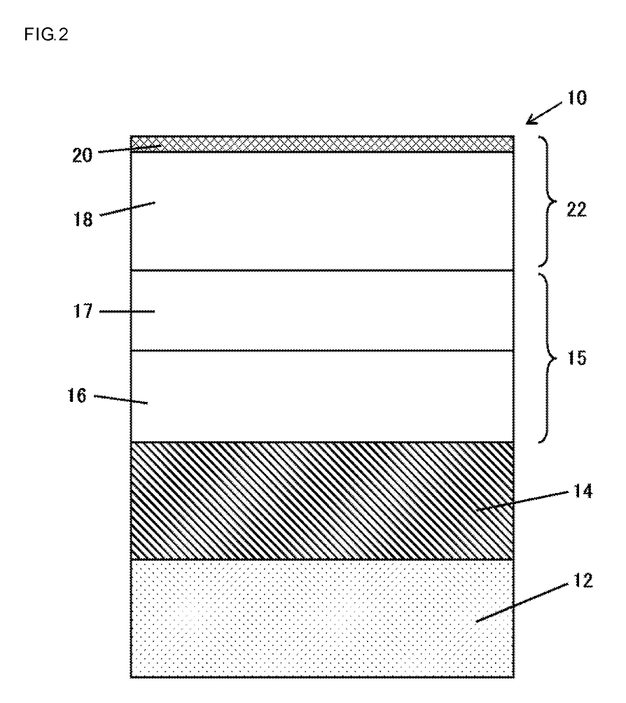

First, a semiconductor substrate which is an example of the present invention will be explained with reference to FIGS. 1 to 2.

FIG. 1 is a diagram showing the depth-direction concentration distribution of the semiconductor substrate which is an example of the present invention, and FIG. 2 is a sectional view of the semiconductor substrate which is an example of the present invention.

A semiconductor substrate 10 shown in FIG. 2 has a substrate 12, a buffer layer 14 provided on the substrate 12, a high-resistance layer 15 provided on the buffer layer 14, the high-resistance layer 15 being composed of a nitride-based semiconductor (for example, GaN) and containing a transition metal and carbon as impurities, and an active layer 22 provided on the high-resistance layer 15.

Here, the substrate 12 is a substrate being composed of, for example, Si or SiC. Moreover, the buffer layer 14 is, for example, a layer formed as a stacked body formed by repeatedly stacking a first layer being composed of a nitride-based semiconductor and a second layer being composed of a nitride-based semiconductor whose composition is different from that of the first layer.

The first layer is composed of, for example, Al_{y}Ga_{1-y}N, and the second layer is composed of, for example, AlₓGa₁₋ₓN (0≦x<y≦1).

Specifically, the first layer may be composed of AlN and the second layer may be composed of GaN.

The active layer 22 has a channel layer 18 composed of a nitride-based semiconductor and a barrier layer 20 composed of a nitride-based semiconductor which is provided on the channel layer 18. The channel layer 18 is composed of, for example, GaN, and the barrier layer 20 is composed of, for example, AlGaN.

The high-resistance layer 15 includes a constant layer 16 in which the transition metal is constant and a reduction layer 17 in contact with the channel layer 18, the reduction layer 17 being the layer in which the transition metal is reduced from the side where the buffer layer 14 is located toward the side where the channel layer 18 is located.

Incidentally, in FIGS. 1 to 2, a case in which the high-resistance layer 15 includes the constant layer 16 is shown, but the high-resistance layer 15 may not include the constant layer 16.

Moreover, the buffer layer 14 may contain Fe and carbon.

In the high-resistance layer 15, a portion in which the carbon concentration is reduced is located in a position closer to the side where the channel layer 18 is located than a portion in which the concentration of the transition metal is reduced, and the position in which the carbon concentration is reduced and the position in which the concentration of the transition metal is reduced are different in a thickness direction. Moreover, the reduction rate at which the carbon concentration is reduced toward the channel layer 18 is higher than the reduction rate at which the concentration of the transition metal is reduced toward the channel layer 18.

As described above, by providing, in the high-resistance layer 15, the reduction layer 17 in contact with the channel layer 18, the reduction layer 17 being the layer in which the concentration of the transition metal is reduced from the side where the buffer layer 14 is located toward the side where the channel layer 18 is located, and making the reduction rate at which the carbon concentration is reduced toward the channel layer 18 higher than the reduction rate at which the concentration of the transition metal is reduced toward the channel layer 18, it is possible to increase the carbon concentration to a region of the reduction layer 17 which is closer to the channel layer 18 and, at the same time, reduce the carbon concentration in the channel layer 18, whereby it is possible to increase the resistance of the high-resistance layer 15 on the side thereof where the channel layer 18 is located while reducing the carbon concentration and the transition metal concentration in the channel layer 18.

In the semiconductor substrate 10, it is preferable that the average carbon concentration of the channel layer 18 is lower than the average carbon concentration of the reduction layer 17.

With such a configuration, it is possible to maintain the high resistance of the reduction layer while suppressing an occurrence of current collapse and a reduction in the mobility of carriers in the channel layer.

In the semiconductor substrate 10, it is preferable that the carbon concentration of the reduction layer 17 to the above-mentioned portion in which the carbon concentration is reduced is increased from the side where the buffer layer 14 is located toward the side where the channel layer 18 is located or is constant.

By making a region in which the carbon concentration is reduced closer to the side where the channel layer is located than a region in which the concentration of the transition metal is reduced, since it is possible to make up for a reduction in the concentration of the transition metal with carbon, it is possible to suppress a reduction in resistance caused by a reduction in the concentration of the transition metal in the reduction layer.

In the reduction layer 17, it is preferable that the sum of the carbon concentration and the transition metal concentration is 1×10¹⁸ atoms/cm³ or more but 1×10²⁰ atoms/cm³ or less.

If the sum of the carbon concentration and the transition metal concentration is within the above-described range, it is possible to maintain the high resistance of the reduction layer suitably.

In the semiconductor substrate 10, it is preferable that the thickness of the reduction layer 17 is 500 nm or more but 3 μm or less and, in the reduction layer 17, the transition metal is reduced from a concentration of 1×10¹⁹ atoms/cm³ or more but 1×10²⁰ atoms/cm³ or less to a concentration of 1×10¹⁶ atoms/cm³ or less.

If the thickness of the reduction layer is 500 nm or more, it is possible to reduce the concentration of the transition metal to a sufficiently low concentration, and, if the thickness of the reduction layer is 3 μm or less, it is possible to prevent the semiconductor substrate from becoming too thick.

Moreover, as the concentration gradient of the transition metal in the reduction layer, the above-described concentration gradient can be suitably used.

As the transition metal, Fe which achieves high resistance more easily than carbon can be adopted. Incidentally, as the transition metal, Sc, Ti, V, Cr, Mn, Co, Ni, Cu, Zn, or the like can also be used.

Incidentally, control of the concentration of Fe can be performed, in addition to the effect of automatic doping by surface segregation or the like, by flow control of Cp₂Fe (bis(cyclopentadienyl)iron).

Since Fe is automatically doped by segregation or the like as described above, it is difficult to reduce the concentration of Fe sharply.

Incidentally, addition of carbon is performed as a result of carbon contained in source gas (such as TMG (trimethylgallium)) being taken in a film when a nitride-based semiconductor layer is grown by MOVPE (metallorganic vapor phase epitaxy), but the addition can also be performed by doping gas such as propane.

Moreover, it is also possible to reduce the carbon concentration sharply by controlling the growth temperature of the nitride-based semiconductor layer, the furnace pressure, or the like.

Therefore, it is possible to reduce the carbon concentration sharply more easily than the concentration of the transition metal such as Fe.

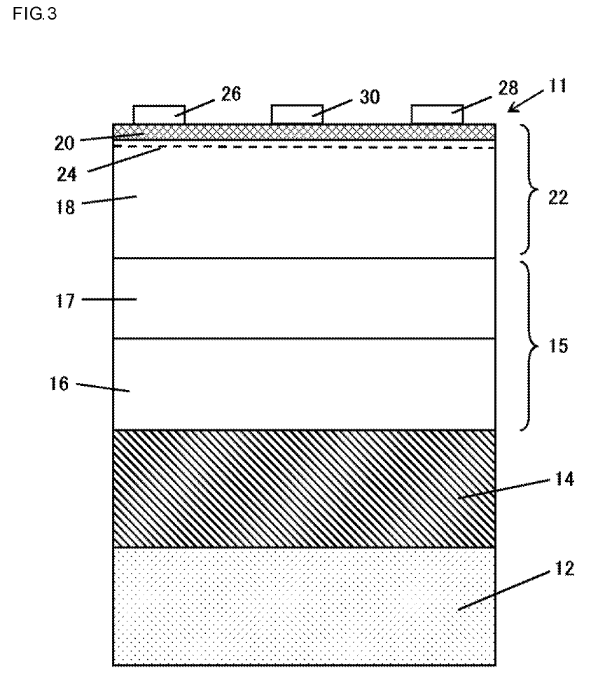

Next, a semiconductor device which is an example of the present invention will be explained with reference to FIG. 3.

FIG. 3 is a sectional view of the semiconductor device which is an example of the present invention.

A semiconductor device 11 is fabricated by using the semiconductor substrate 10 which is an example of the present invention and has a first electrode 26, a second electrode 28, and a control electrode 30 which are provided on the active layer 22.

In the semiconductor device 11, the first electrode 26 and the second electrode 28 are disposed in such a way that an electric current flows to the second electrode 28 from the first electrode 26 via a two-dimensional electron gas layer 24 formed in the channel layer 18.

The electric current flowing between the first electrode 26 and the second electrode 28 can be controlled by a potential which is applied to the control electrode 30.

The semiconductor device 11 is fabricated by using the semiconductor substrate 10 which is an example of the present invention. The above semiconductor device 11 can increase the carbon concentration to a region of the reduction layer 17 which is closer to the side where the channel layer 18 is located and, at the same time, reduce the carbon concentration in the channel layer 18, which makes it possible to reduce the carbon concentration and the transition metal concentration in the channel layer 18 while maintaining the high resistance of the high-resistance layer 15 on the side where the channel layer is located, and by increasing the vertical and transverse electrical resistance while suppressing a reduction in the mobility of carriers in the channel layer 18, it is possible to improve the OFF characteristics of a transistor and make the transistor withstand a higher voltage by the suppression of vertical leakage.

### EXAMPLES

Hereinafter, the present invention will be described more specifically with Example and Comparative Examples, but the present invention is not restricted thereto.

### Example

In the semiconductor substrate 10 of FIG. 2, a silicon substrate was used as the substrate 12, a stacked body formed by repeatedly stacking an AlN layer and a GaN layer and containing Fe added thereto was used as the buffer layer 14, a GaN layer was used as the high-resistance layer 15, and the reduction layer 17 in which the concentration of Fe is reduced was provided in the high-resistance layer 15.

Moreover, setting was made such that, in a region at a depth of about 1 μm from the surface of the semiconductor substrate 10, the concentration of Fe was reduced to a concentration of about 1×10¹⁶ atoms/cm³ or less. Incidentally, control of the concentration of Fe was performed, in addition to the effect of automatic doping by segregation, by flow control of Cp₂Fe (bis(cyclopentadienyl)iron).

Furthermore, in the reduction layer 17, carbon was added such that the carbon concentration was increased toward the surface in order to make up for a reduction in the concentration of Fe.

In addition, setting was made such that, in a region at a depth of about 1 μm from the surface of the semiconductor substrate 10, the carbon concentration was sharply reduced to a concentration of about 1×10¹⁶ atoms/cm³.

In this Example, since Fe is added to the high-resistance layer 15, it is possible to achieve high resistance effectively.

The concentration profile of the semiconductor substrate fabricated in the above-described manner was measured by SIMS analysis. As a result, it was confirmed that the carbon concentration and the Fe concentration had the concentration distributions shown in FIG. 1.

By using the above-described semiconductor substrate, the semiconductor device as shown in FIG. 3 was fabricated.

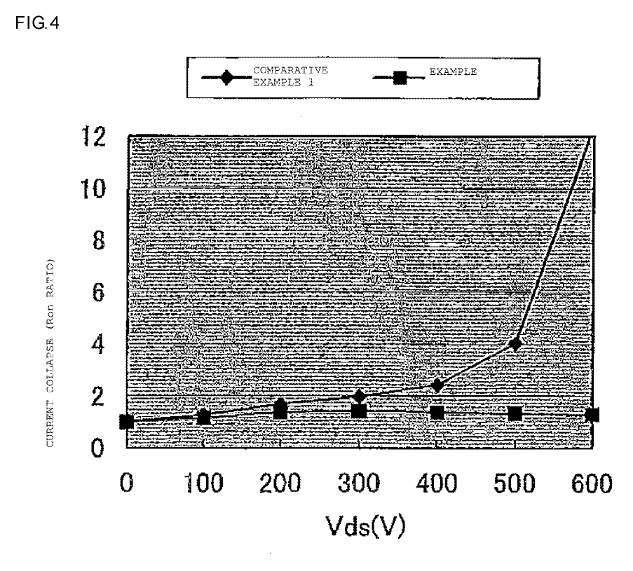

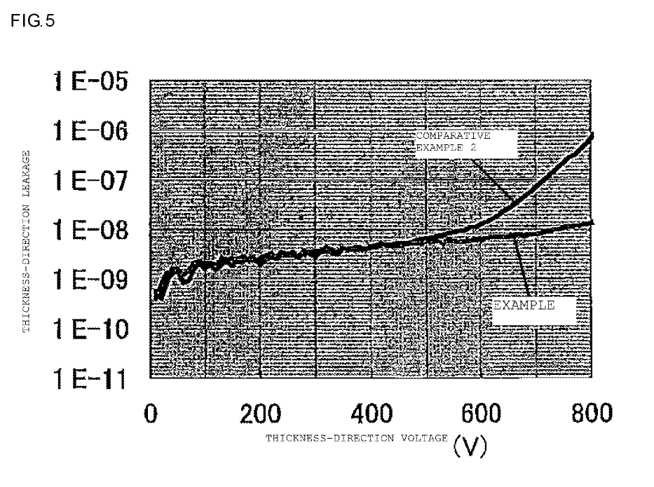

In the fabricated semiconductor device, the Vds (the potential difference between the electrode 26 and the electrode 28) dependence of current collapse and the relationship between a vertical leakage current and a vertical voltage were measured. The result is shown in FIGS. 4 to 5. Incidentally, the vertical axis of FIG. 4 represents the R_{ON} ratio defined as R_{ON}′/R_{ON}: the ratio between ON resistance R_{ON} in a non-collapse state (normal state) and ON resistance R_{ON}′ in a collapse state, and the R_{ON} ratio indicates how much the ON resistance has increased by collapse.

### Comparative Example 1

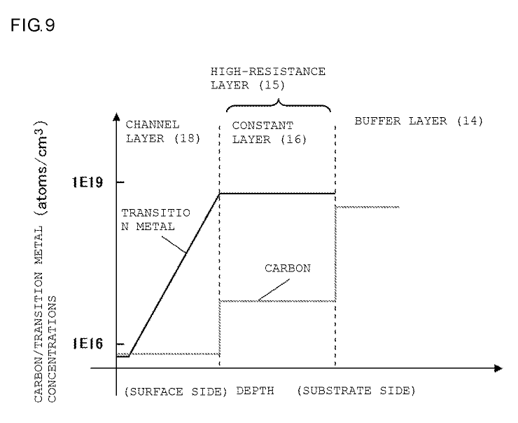

A semiconductor substrate was fabricated in the same manner as in Example. However, the reduction layer was not formed, and the semiconductor substrate was made to have a depth-direction concentration distribution as shown in FIG. 9. In the semiconductor substrate of Comparative Example 1, Fe is contained in the channel layer 18 like a skirt trailed.

By using the above-described semiconductor substrate, the semiconductor device as shown in FIG. 3 (in which the reduction layer 17 was not formed, though) was fabricated.

In the fabricated semiconductor device, the Vds (the potential difference between the electrode 26 and the electrode 28) dependence of current collapse was measured. The result is shown in FIG. 4.

### Comparative Example 2

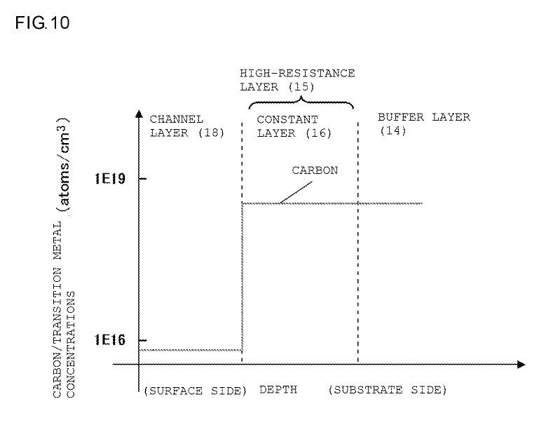

A semiconductor substrate was fabricated in the same manner as in Example. However, Fe was not added to the high-resistance layer 16 and only carbon was added, and the semiconductor substrate was made to have a depth-direction concentration distribution shown in FIG. 10.

By using the above-described semiconductor substrate, the semiconductor device as shown in FIG. 3 (in which the reduction layer 17 was not formed, though) was fabricated.

In the fabricated semiconductor device, the relationship between the vertical leakage current and the vertical voltage was measured. The result is shown in FIG. 5.

As is clear from FIG. 4, in the semiconductor device of Example, current collapse is suppressed compared to the semiconductor device of Comparative Example 1. This is considered to be achieved by a sufficient reduction in the Fe and carbon concentrations in the channel layer.

Moreover, as is clear from FIG. 5, in the semiconductor device of Example, the vertical leakage current is low compared to the semiconductor device of Comparative Example 2. This is considered to be achieved by the implementation of higher resistance in the reduction layer as a result of a reduction in the Fe concentration in the reduction layer being made up for with carbon.

It is to be understood that the present invention is not limited in anyway by the embodiment thereof described above. The above embodiment is merely an example, and anything that has substantially the same structure as the technical idea recited in the claims of the present invention and that offers similar workings and benefits falls within the technical scope of the present invention.

1-8. (canceled)

9. A semiconductor substrate comprising:
a substrate;
a buffer layer provided on the substrate;
a high-resistance layer provided on the buffer layer, the high-resistance layer being composed of a nitride-based semiconductor and containing a transition metal and carbon; and
a channel layer provided on the high-resistance layer, the channel layer being composed of a nitride-based semiconductor,
wherein
the high-resistance layer includes a reduction layer in contact with the channel layer, the reduction layer being the layer in which a concentration of the transition metal is reduced from a side where the buffer layer is located toward a side where the channel layer is located, and
a reduction rate at which a carbon concentration is reduced toward the channel layer is higher than a reduction rate at which the concentration of the transition metal is reduced toward the channel layer.

10. The semiconductor substrate according to claim 9, wherein
an average carbon concentration of the channel layer is lower than an average carbon concentration of the reduction layer.

11. The semiconductor substrate according to claim 9, wherein
a carbon concentration of the reduction layer on the side where the buffer layer is located to a portion in which the carbon concentration is reduced is increased from the side where the buffer layer is located toward the side where the channel layer is located or is constant.

12. The semiconductor substrate according to claim 10, wherein
a carbon concentration of the reduction layer on the side where the buffer layer is located to a portion in which the carbon concentration is reduced is increased from the side where the buffer layer is located toward the side where the channel layer is located or is constant.

13. The semiconductor substrate according to claim 9, wherein
in the reduction layer, a sum of the carbon concentration and the transition metal concentration is 1×10¹⁸ atoms/cm³ or more but 1×10²⁰ atoms/cm³ or less.

14. The semiconductor substrate according to claim 10, wherein
in the reduction layer, a sum of the carbon concentration and the transition metal concentration is 1×10¹⁸ atoms/cm³ or more but 1×10²⁰ atoms/cm³ or less.

15. The semiconductor substrate according to claim 11, wherein
in the reduction layer, a sum of the carbon concentration and the transition metal concentration is 1×10¹⁸ atoms/cm³ or more but 1×10²⁰ atoms/cm³ or less.

16. The semiconductor substrate according to claim 12, wherein
in the reduction layer, a sum of the carbon concentration and the transition metal concentration is 1×10¹⁸ atoms/cm³ or more but 1×10²⁰ atoms/cm³ or less.

17. The semiconductor substrate according to claim 9, wherein
a thickness of the reduction layer is 500 nm or more but 3 μm or less and, in the reduction layer, the transition metal is reduced from a concentration of 1×10¹⁹ atoms/cm³ or more but 1×10²⁰ atoms/cm³ or less to a concentration of 1×10¹⁶ atoms/cm³ or less.

18. The semiconductor substrate according to claim 10, wherein
a thickness of the reduction layer is 500 nm or more but 3 μm or less and, in the reduction layer, the transition metal is reduced from a concentration of 1×10¹⁹ atoms/cm³ or more but 1×10²⁰ atoms/cm³ or less to a concentration of 1×10¹⁶ atoms/cm³ or less.

19. The semiconductor substrate according to claim 11, wherein
a thickness of the reduction layer is 500 nm or more but 3 μm or less and, in the reduction layer, the transition metal is reduced from a concentration of 1×10¹⁹ atoms/cm³ or more but 1×10²⁰ atoms/cm³ or less to a concentration of 1×10¹⁶ atoms/cm³ or less.

20. The semiconductor substrate according to claim 12, wherein
a thickness of the reduction layer is 500 nm or more but 3 μm or less and, in the reduction layer, the transition metal is reduced from a concentration of 1×10¹⁹ atoms/cm³ or more but 1×10²⁰ atoms/cm³ or less to a concentration of 1×10¹⁶ atoms/cm³ or less.

21. The semiconductor substrate according to claim 9, wherein
the high-resistance layer further includes a layer in which the concentration of the transition metal is constant.

22. The semiconductor substrate according to claim 10, wherein
the high-resistance layer further includes a layer in which the concentration of the transition metal is constant.

23. The semiconductor substrate according to claim 11, wherein
the high-resistance layer further includes a layer in which the concentration of the transition metal is constant.

24. The semiconductor substrate according to claim 12, wherein
the high-resistance layer further includes a layer in which the concentration of the transition metal is constant.

25. The semiconductor substrate according to claim 9, wherein
the transition metal is Fe.

26. The semiconductor substrate according to claim 10, wherein
the transition metal is Fe.

27. A semiconductor device that is fabricated by using the semiconductor substrate according to claim 9, wherein
an electrode is provided on the channel layer.

28. A semiconductor device that is fabricated by using the semiconductor substrate according to claim 10, wherein
an electrode is provided on the channel layer.
